(19) United States
(12) Patent Application Publication
(10) Pub. No.: US 2010/0001724 A1
(43) Pub. Date: Jan. 7, 2010

(54) IC Microfluidic Platform With Integrated Magnetic Resonance Probe

(75) Inventor: Rizwan Bashirullah, Gainesville, FL (US)

Correspondence Address: SALIWANCHIK LLOYD & SALIWANCHIK;A PROFESSIONAL ASSOCIATION, PO Box 142950, GAINESVILLE, FL, 32614, US

(73) Assignee: UNIVERSITY OF FLORIDA RESEARCH FOUNDATION, INC, GAINESVILLE, FL (US)

(21) Appl. No.: 12/300,872

(22) PCT Filed: May 18, 2007
(86) PCT No.: PCT/US07/12010

§ 371 Date: Apr. 30, 2009

Related U.S. Application Data
(60) Provisional application No. 60/802,254, filed on May 18, 2006.

(51) Int. Cl. G01R 33/48; G01R 1/06; H01L 21/00; G01R 33/44

(52) U.S. Cl. 324/307; 324/149; 438/49; 324/318; 257/E21.001

(57) ABSTRACT

An integrated hybrid microfluidic-IC platform for single cell manipulation and microscopy and method for making the platform. In particular, the integrated platform can incorporate a planar microcoil embedded in a silicon substrate that is subsequently used to fabricate a CMOS IC for the platform. The CMOS IC circuitry provides a two dimensional array of microsites that can incorporate an electrode (microelectrode), sensors, and control logic. A direct conversion receiver (DCR) can also be embedded within the CMOS circuitry to create an integrated IC platform. A microfluidic chamber can be formed on the integrated IC platform. The integrated hybrid platform can provide an increased sensitivity for mass limited samples and high resolution manipulation of biological cells. In addition, individual cell manipulation can be performed via dielectrophoresis (DEP).

### CROSS-REFERENCE TO RELATED APPLICATION

The present application claims the benefit of U.S. application Ser. No. 60/802,254, filed May 18, 2006, which is hereby incorporated by reference herein in its entirety, including any figures, tables, or drawings.

### BACKGROUND OF INVENTION

Magnetic Resonance Microscopy (MRM) is the modality of choice for structural and conformational determination of biophysical and biochemical information content that is unavailable with traditional imaging techniques such as optical microscopy [1]-[8]. MRM's significance stems from the rich array of contrast variables used to study, for example, relaxation times T1 and T2, presence of flow and diffusion, and proton density [2]. For instance, as discussed by Ciobanu et al. in “Magnetic Resonance Imaging of Biological Cells”, Progress in Nuclear Resonance Spectroscopy, Vol. 42, pp. 69-73, 2003, MRM has been shown to be useful in the study of cell response to external stimuli, contributing to a better understanding of the response of both healthy and cancerous cells to various forms of cancer treatment.

Accordingly, there is a need for an MRM platform that can be easily produced and can provide increased sensitivity for analysis of mass limited samples while providing high resolution manipulation of biological cells.

### BRIEF SUMMARY

The subject invention pertains to a method and apparatus for integrating an integrated circuit (IC)-microfluidic platform with magnetic resonance probe for sample-limited cell analysis and manipulation. An embodiment of the subject invention provides an integrated nuclear magnetic resonance (NMR) probe and direct conversion receiver (DCR). Embodiments of the subject platform can perform single cell manipulation and magnetic resonance microscopy (MRM).

Embodiments of the subject IC-microfluidic integrated platform can provide (1) improved signal-to-noise ratio (SNR), (2) increased cell manipulation flexibility and (3) platform miniaturization for space limited high-field MRI systems. The subject platform can incorporate an integrated circuit (IC) hybrid microsystem for increased sensitivity with respect to analysis of mass limited samples while providing high resolution (˜microns) manipulation of biological cells.

Embodiments of the invention pertain to a microcoil NMR probe. Further embodiments relate to the integration of an integrated circuit microfluidic platform with a microcoil NMR probe in complementary metal oxide semiconductor (CMOS) technology. In a specific embodiment, the integrated platform and NMR probe can be accomplished in complementary metal oxide semiconductor (CMOS) technology. Further embodiments relate to an RF subsystem receiver in CMOS technology. In a specific embodiment, a microfluidic platform, an NMR microcoil NMR probe, and an RF receiver are integrated in a single CMOS microchip. The subject platform, NMR probe, and/or RF receiver can be accomplished in other solid state technologies, such as GaAs FET, bipolar technology, and GaAs based technology.

### BRIEF DESCRIPTION OF DRAWINGS

FIGS. 1A and 1B show a microchannel chamber formed on top of an integrated circuit (IC) according to an embodiment of the subject invention. FIG. 1A shows a cut away perspective view and FIG. 1B shows a partial cross-sectional view.

FIG. 2 shows a chip architecture of a cell manipulation microsystem in accordance with an embodiment of the subject invention.

FIGS. 3A and 3B show an embodiment of microfluidic package fabrication assembly and flow, respectively.

FIG. 4 shows a circuit of a direct conversion receiver (DCR) for magnetic resonance imaging in accordance with an embodiment of the subject invention.

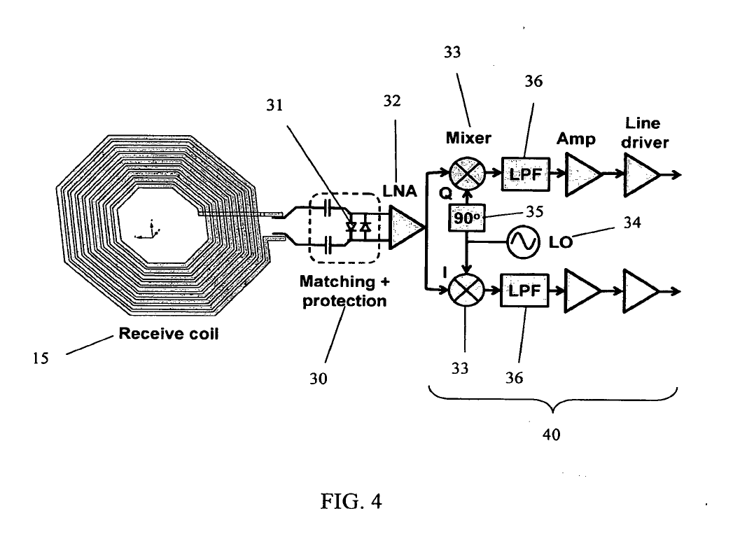

### DETAILED DISCLOSURE

The subject invention pertains to a method and apparatus for integrating an integrated circuit (IC)-microfluidic platform with magnetic resonance probe for sample-limited cell analysis and manipulation. An embodiment of the subject invention provides an integrated nuclear magnetic resonance (NMR) probe and direct conversion receiver (DCR) Embodiments of the subject platform can perform single cell manipulation and magnetic resonance microscopy (MRM).

Embodiments of the subject IC-microfluidic integrated platform can provide (1) improved signal-to-noise ratio (SNR), (2) increased cell manipulation flexibility and (3) platform miniaturization for space limited high-field MRI systems. The subject platform can incorporate an integrated circuit (IC) hybrid microsystem for increased sensitivity with respect to analysis of mass limited samples while providing high resolution (˜microns) manipulation of biological cells.

Embodiments of the invention pertain to a microcoil NMR probe in complementary metal oxide semiconductor (CMOS) technology. Further embodiments relate to the integration of an integrated circuit microfluidic platform with a microcoil NMR probe in complementary metal oxide semiconductor (CMOS) technology. In a specific embodiment, the integrated platform and NMR probe can be accomplished in complementary metal oxide semiconductor (CMOS) technology. Further embodiments relate to an RF subsystem receiver in CMOS technology. In a specific embodiment, a microfluidic platform, an NMR microcoil NMR probe, and an RF receiver are integrated in a single CMOS microchip. The subject platform, NMR probe, and/or RF receiver can be accomplished in other solid state technologies, such as GaAs FET, bipolar technology, and GaAs based technology.

### IC/Microfluidic Platform for Individual Cell Manipulation

In an embodiment, the subject platform can incorporate a microchamber defined by a two dimensional array of microsites and a conductive glass lid. Other conductive lids or lids with conductive materials can also be used. In an embodiment, the conductive lid acts as a ground plane. In a specific embodiment, each microsite incorporates an electrode (microelectrode), sensors, and control logic, which are implemented using standard CMOS technology. The microelectrodes allow the application of static and/or ac electric fields to a microchamber for holding fluids with cells to be manipulated and imaged. The electric fields can extend from the microelectrodes to the conductive lid. Embodiments of the subject invention can incorporate an integrated radio frequency (RF) subsystem. The RF subsystem can incorporate a NMR probe and a RF receiver. In one embodiment, a planar microcoil and a direct conversion receiver (DCR) are embedded within the CMOS circuitry. The DCR can receive a weak magnetic resonance imaging (MRI) signal, for example, at 750 MHz.

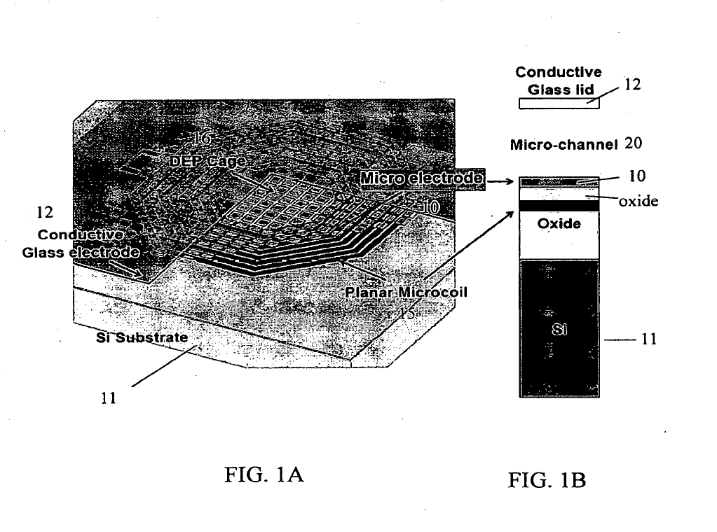

An embodiment of a microchamber of the hybrid IC-microfluidic platform is illustrated schematically in FIGS. 1A and 1B. Referring to FIG. 1A, a planar microcoil 15 is positioned on a silicon substrate 11. This substrate 11 can be used to fabricate any needed CMOS circuitry (not shown). An array of microelectrodes 10 can be formed on the substrate 11 above the planar microcoil 15. In a specific embodiment, the array of microelectrodes 10 are fabricated on the topmost metal layer. The microelectrodes 10 can be protected from liquid in the microchamber by standard CMOS passivation. A conductive glass electrode can be formed above the array of microelectrodes 10 to form a conductive lid 12. Electric fields are selectively produced between the surface of the microelectrodes 10 of the array of microelectrodes 10 and the conductive overlid 12.

In alternative embodiments, the RF probe can be located in alternative positions so as to be able to transmit and/or receive RF signals from the area of interest in the microchamber. Alternative positions for the RF probe include, but are not limited to, on top of the array of microelectrodes 10, to the side of the microchamber, and on top of the microchamber. In a specific embodiment with the RF probe on top of the array of microelectrodes 10, a layer of oxide can be positioned between the microelectrodes 10 and the RF probe. In specific embodiments with the RF probe above the microchamber, the RF probe can be above the lid or below the lid and an insulating material can be positioned between the RF probe and the lid. Preferably, the RF probe is positioned so the plane of the RF probe is a distance away from the location to be imaged approximately equal to the radius of the RF probe, where the radius of the probe can be considered to be the mean of the radius of the outer loop of the RF probe and the radius of the inner loop of the RF probe. Referring to FIGS. 1A and 1B, in a specific embodiment the gap between the conductive lid 12 and the microelectrode 10 can be on the order of 100 μm and the planar microcoil 15 can be located a distance below the midpoint of the gap of about one-half of the width of the gap between the lid 12 and the microelectrode 10.

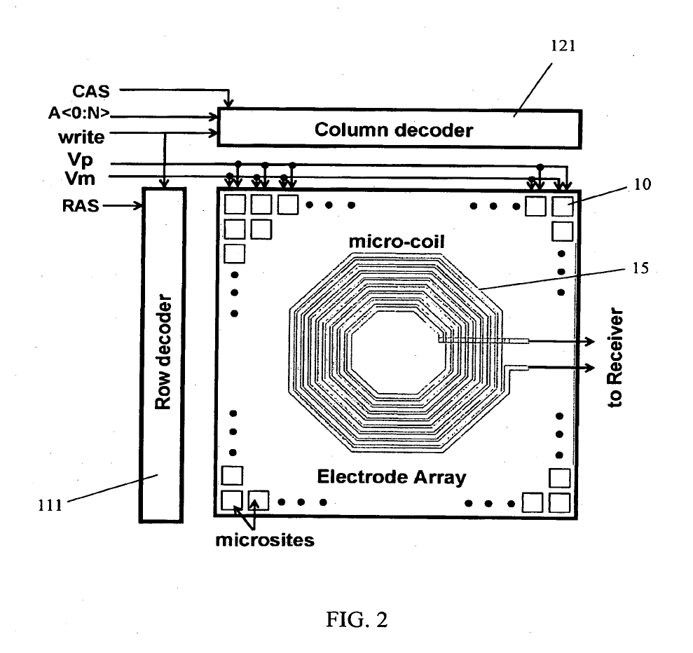

The subject microchamber can be sectioned into microsites where each microsite incorporates one microelectrode 10 of the array of microelectrodes 10. In operation, the array of microelectrodes 10 can selectively produce electric fields between the surface of the array of microelectrodes 10 and a conductive glass lid 12 such that one or more electric fields can be produced in a corresponding one or more microsites, as desired. Control logic can be utilized to control the electric fields as desired. Embodiments of the subject invention provide the ability to control the location and/or orientation of a cell by application of electric fields via the microelectrodes and lid contemporaneously with imaging the cell via MRI by transmitting and receiving RF pulses through the RF probe. The electric fields can be turned off prior to transmitting the RF pulse and turned back on, if desired, after receiving the RF pulse. Alternatively, the electric fields can be on during MR imaging. The layout and design of the microelectrodes 10 can vary. FIGS. 1A, 1B, and 2 illustrate an embodiment with a two-dimensional array of rectangular electrodes. Other patterns can use, for example, annular-shaped electrodes surrounding a circular electrode for use to create a microsite, as well as other shaped electrodes and/or electrode layout pattern to the needs of the application.

Biological cells can be suspended in a medium between the microsites and the glass lid 12. Referring to FIG. 1B, the space between the conductive lid 12 and the microelectrode 10 can form a microchannel 20 where the fluidic medium can flow.

Individual cell manipulation can be achieved via dielectrophoresis (DEP), a physical phenomenon whereby neutral particles experience a net directional force in response to a spatially non-uniform electric field. In an embodiment, the biological cells can be manipulated via negative dielectrophoresis (nDEP). DEP cages 16 can be created above a microelectrode 10 by connecting the microelectrode 10 and the glass lid 12 to a counter-phase sinusoidal voltage and the microelectrodes surrounding the microelectrode 10 to an in-phase sinusoidal voltage. How to manipulate and cage cells is known in the art. An example of how to accomplish such a DEP cage is taught in N. Manaresi, et. al., “A CMOS Chip for Individual Cell manipulation and Detection,” IEEE Journal of Solid-State Circuits, Vol. 38, No. 12, pp. 2297-2305, Dec. 2003, the teachings of which are herein incorporated by reference. In embodiments, the array of microelectrodes can be programmed to change the field distribution in the spatial region above the microelectodes.

The array of microelectrodes can be programmed under software control to change the field distribution in the spatial region above the microsites. Programming can be accomplished by loading an actuation pattern into the microsite circuits. In an embodiment, referring to FIG. 2, the microsite circuits incorporate an actuation circuit and a 1-bit memory cell addressable in random via row decoder 111 and column decoder 121 much like an SRAM circuit. FIG. 2 shows a schematic for the microsite circuits for an embodiment of the subject invention. In a specific embodiment, the microsite circuits can be fabricated on the substrate 11. The active electrode array area can be made to span most of the available silicon area. In one embodiment, the active electrode array can be approximately 2×2 mm². In an embodiment, for manipulation of small cells, for example <100 μm, the pitch of the array elements is set to 100 μm for a 20×20 element electrode array, where the pitch is the distance from the center of a microelectrode to the center of an adjacent microelectrode. However, the size and pitch can be easily changed to manipulate different sized cells. Specific embodiments can employ 500 μm×500 μm microelectrodes, microelectrodes 100 μm×100 μm or smaller, and microelectrodes 50 μm×50 μm. Of course, a variety of sizes can be employed. The size of these DEP cages 16 can also be easily increased by applying the appropriate electronically controlled voltage patterns to multiple electrodes.

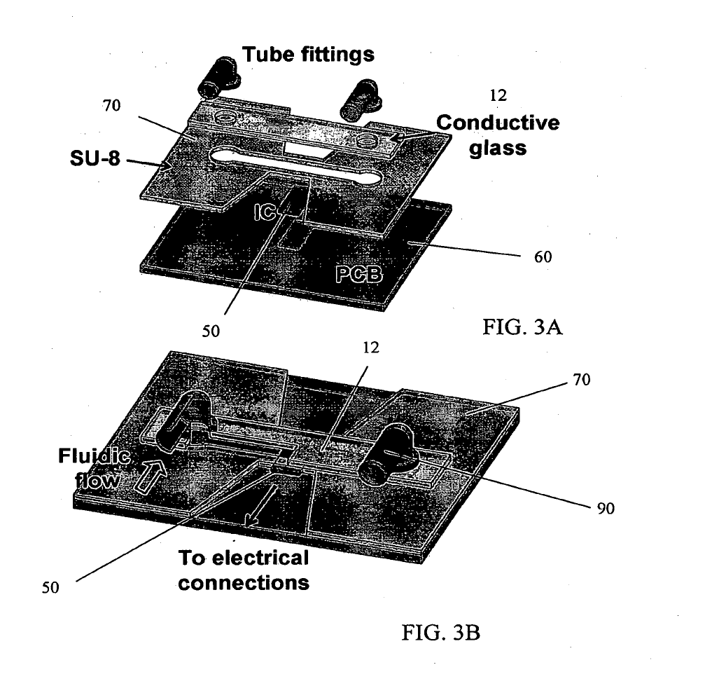

In a specific embodiment, the subject platform can be created by forming a planar microcoil on a substrate and fabricating a CMOS IC on the substrate. Referring to FIG. 3A, a CMOS IC 50 with embedded planar microcoil 15 can then be attached to a silicon wafer or polychlorinated biphenyl (PCB) 60 having electrical lithographically patterned electrical connections (not shown). The silicon wafer or PCB 60 with attached CMOS IC 50 with embedded planar microcoil 15 can be covered with photoresist 70. In an embodiment, the photoresist 70 can be a negative photoresist such as SU-8. The photoresist can be patterned to define the sidewalls of the micro-chamber and to provide open areas for wirebonding to the chip 50 for external connections. The channel height can be controlled by varying the thickness of the photoresist layer. Holes can then be drilled on the conductive glass 12 for fluidic tube fittings 90. Then a conductive glass lid 12 can be sealed on top of the channel sidewalls to define the microchannel.

In an embodiment, the glass lid 12 can be formed by optically transparent indium thin oxide (ITO). In an embodiment, the coverslip or lid 12 can be spaced about 3-400 μm from the chip surface. The strength of the DEP cage can be controlled by changing the lid-voltage amplitude and does not necessarily rely on accurate control of the spacing of the glass lid 12 from the chip surface.

### Planar Microcoil Based MR Probe

A planar microcoil can be embedded within the die underneath the electrode arrays for MR signal detection. In a specific embodiment, the spatial sensitivity of a 360 μm inner diameter multi-turn planar microcoil placed below an array of electrodes at 150 μm pitch can be obtained by computing the B field using finite element analysis (FEM). A surface plot of the B_{xy} at z=240 μm above the coil plane indicates a relative homogeneous distribution within approximately 250 μm by 250 μm area above the microcoil for this embodiment example. The peak B-field sensitivity in the xy-plane at z=240 μm above the coil surface is approximately 1.56 mT (including the effect of electrode array). The design of the MR microcoil probe can be optimized for SNR with proper impedance match to the integrated receiver. In an embodiment, the microcoils are fabricated using Aluminum (volume susceptibility ˜+1.645×10⁻⁶) and copper (volume susceptibility ˜−0.768×10⁻⁶) interconnects (available 130 nm node and below). The microcoils can incorporate one or more layers of Aluminum and one or more layers of copper to reduce the net susceptibility and, in a specific embodiment, achieve a susceptibility near zero. The metals can be selected to compensate for perturbations in the applied B field due to the magnetic susceptibility mismatch of microcoil conductor composition. To further minimize the effects of spectral linewidth broadening, the IC-microfluidic assembly can be immersed in liquid fluorocarbon (FC-43). Digital trimming can be performed to compensate the effect of high magnetic fields on device performance and device bias points.

Specific embodiments of the IC-microfluidic assembly with MR microcoil probe can allow the physical relation between the array of microelectrodes and the RF probe to be controlled to within microns and, in a further specific embodiment within nanometers. In the embodiment shown in FIGS. 1 and 2, a polygonal spiral-shaped RF probe is shown. Additional embodiments can incorporate other RF probe shapes and configurations well known in the art, such as, but not limited to, circular, rectangular, multiple coils, and phased array coils.

### RF Subsystem and Circuit Design

FIGS. 5 and 6 show a specific embodiment of a circuit of, and layout design of, a direct conversion receiver (DCR), respectively, in accordance with the subject invention. Referring to the embodiment shown in FIGS. 5 and 6, the overall receive chain incorporates an MR microcoil 15, matching network 30 with protection cross coupled diodes 31, and a direct conversion receiver (DCR) 40. A low noise amplifier (LNA) 32 drives RF input ports of two mixers 33. The two mixers 33 are identical. A local oscillator (LO) input port of these mixers 33 is driven in quadrature phase. In an embodiment, an external and very stable PTS (programmed test source) frequency reference of 750 MHz can be supplied externally from the MRI system to the chip 50. The LO signal 34 can be buffered to drive a 90 degree phase-shift network 35, and can be followed by limiters to stabilize the amplitude and set the appropriate common-mode voltage for the mixers. Quadrature phases can be derived by passing the buffered LO through an RC poly-phase network. Errors in quadrature from inaccuracies in the actual values of R and C can be compensated for by digital on-chip trimming. The output of the mixers 33 can be driven through low pass filters 36. In one embodiment, the output of the mixer 33 can be filtered by an integrated differential Butterworth filter. The entire received path can be made differential in order to improve common mode rejection. Once the signal from the precessing magnetization is down converted, it can be buffered to drive 50 Ω cables to an external computer or processor.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

### REFERENCES

1. Peck T L, Magin R L, Lauterbur P C. Design and analysis of microcoils for NMR microscopy. J Magn Reson B 108:114-144 (1995).
2. Schoeniger J S, Aiken N, Hsu E, Blackband S J, “Relaxation-Time and Diffusion NMR Microscopy of Single Neurons. J. Magn. Reson. B, 103, 261-273 (1994).
3. L. Ciobanu, A. Webb, C. Pennington, “Magnetic resonance imaging of biological cells,” Progress in Nuclear Resonance Spectroscopy,“ Vol. 42, pp. 69-93, 2003.
4. Aiken N R, Hsu E W, Blackband S J. A Review of NMR Microimaging Studies of Single Cells. J Magn Reson Anal. 1:41-48 (1995)
5. Callaghan P T. “Principles of NMR Microscopy”. Oxford University Press, Oxford (1991)
6. Aguayo J B, Blackband S J, Schoeniger J, Mattingly M, Hintermann M. Nuclear magnetic resonance imaging of a single cell. Nature 322:190-191 (1986)
7. Hsu E W, Aiken N R, Blackband S J. NMR Microscopy of Single Neurons Under Hypotonic Perturbation. Am J Physiol 271:C1295-C1302 (1996)
8. A. G. Webb and S. C. Grant, Signal-to-noise and magnetic susceptibility trade-offs in solenoidal microcoils. J Magn Reson 113:83-87 (1996)
9. T. B. Jones, “Basic Theory of Dielectrophoresis,” IEEE Eng. in Med. and Biology Magazine, pp. 33-42, December 2003.
10. N. Manaresi, et. al., “A CMOS Chip for Individual Cell manipulation and Detection,” IEEE Journal of Solid-State Circuits, Vol. 38, No.12, pp. 2297-2305, December 2003.
11. C.-M Ho, “Fluidics-the link between micro and nano sciences and technologies-,” in Proc. IEEE Int. Conf. MEMS, Interlaken, Switzerland, January 2001, pp. 375-384.
12. C. Massin, et. al, “Planar microcoil-based microfluidic NMR probes,” J. of Mag. Res., Vol. 164, pp. 242-255, 2003.
13. A. G. Webb, “Radiofrequency microcoils in magnetic resonance,” Progress in Nuclear Resonance Spectroscopy,” Vol. 31, pp. 1-42, 1997.
14. K. Kurpad, E. B. Boskamp, C. Bulkes, “Volume RF Transmit Coil with Integrated Power MOSFETs,” 10th Proc. ISMRM, 2002.
15. B. Razavi, “Design Considerations for Direct-Conversion Receivers,” IEEE Trans. Circuits and Systems II: Analog and Digital Sig. Proc., Vol. 44, No. 6, pp. 428-435, June 1997.

What is claimed is:

1. An apparatus for manipulation and analysis of a cell, comprising:
an integrated circuit (IC) microfluidic platform, wherein the IC microfluidic platform comprises a microchannel for the flow of a fluidic medium having a suspended cell,
a plurality of microelectrodes;
an electrode;
a voltage source, wherein a voltage applied between one or more of the plurality of microelectrodes and the electrode by the voltage source creates an electric field in a region of interest within the microchannel capable of manipulation of the suspended cell; and
an RF probe integrated with the IC microfluidic platform, wherein the RF probe is positioned to image the region of interest within the microchannel.

2. The apparatus according to claim 1, wherein the plurality of microelectrodes comprises a two-dimensional array of microelectrodes.

3. The apparatus according to claim 1, wherein the electrode is a conductive lid.

4. The apparatus according to claim 3, wherein the conductive lid comprises indium tin oxide (ITO).

5. The apparatus according to claim 1, further comprising a direct conversion receiver (DCR) capable of receiving a weak magnetic resonance imaging (MRI) signal.

6. The apparatus according to claim 1, wherein the RF probe comprises a planar microcoil.

7. The apparatus according to claim 6, wherein the RF probe is formed using complementary metal oxide semiconductor (CMOS) technology.

8. The apparatus according to claim 1, wherein both the microfluidic platform and the RF probe are formed using CMOS technology.

9. The apparatus according to claim 1, wherein the RF probe comprises:
an RF microcoil electrically connected to a matching network with protection cross coupled diodes;
a low noise amplifier a matching network electrically connected to the RF microcoil;
a low noise amplifier electrically connected to the matching network; and
a direct conversion receiver driven by the low noise amplifier.

10. The apparatus according to claim 9, wherein the direct conversion receiver comprises:
a first mixer and a second mixer receiving input from the low noise amplifier, wherein the first mixer and the second mixer are identical mixers;
a local oscillator for driving the first mixer and the second mixer in quadrature phase, wherein the local oscillator is buffered to drive a 90 degree phase-shift network, and is followed by limiters to stabilize the amplitude and set the appropriate common-mode voltage for the first mixer and the second mixer;
a first low pass filter and a second low pass filter connected to the outputs of the first mixer and the second mixer, respectively;
a first amplifier and a second amplifier connected to the outputs of the first low pass filter and the second low pass filter, respectively; and
a first line driver and a second line driver connected to the outputs of the first amplifier and the second amplifier, respectively.

11. The apparatus according to claim 1, further comprising a CMOS passivation layer formed on the plurality of microelectrodes to protect the microelectrodes from liquid.

12. The apparatus according to claim 1, wherein the RF probe comprises an RF microcoil, wherein the RF microcoil is positioned under the plurality of microelectrodes with an insulating layer formed therebetween.

13. The apparatus according to claim 8, wherein the plurality of microelectrodes are fabricated on a topmost metal layer.

14. The apparatus according to claim 1, wherein the RF probe comprises an RF microcoil, wherein the RF microcoil is positioned above the plurality of microelectrodes with an insulating layer formed therebetween.

15. The apparatus according to claim 1, wherein the RF probe comprises an RF microcoil, wherein the RF microcoil is positioned to a side of the plurality of microelectrodes.

16. The apparatus according to claim 1, wherein the RF probe comprises an RF microcoil, wherein the RF microcoil is positioned above the electrode with an insulating layer formed therebetween.

17. The apparatus according to claim 1, wherein the RF probe comprises an RF microcoil, wherein the RF microcoil is positioned below the electrode with an insulating layer formed therebetween.

18. The apparatus according to claim 1, further comprising control logic to control the voltage source, wherein the control logic is capable of providing the ability to control the location and/or orientation of a cell by application of electric fields via the microelectrodes and electrode contemporaneously with imaging the cell via the RF probe.

19. The apparatus according to claim 1, wherein the RF probe comprises a RF planar microcoil, wherein the RF microcoil is positioned so the plane of the RF planar microcoil is a distance away from a center of the region of interest approximately equal to the radius of the RF planar microcoil, where the radius of the probe is the mean of the radius of an outer loop of the planar microcoil and the radius of an inner loop of the planar microcoil.

20. The apparatus according to claim 7, wherein the RF probe comprises a RF microcoil having a magnetic susceptibility near zero.

21. The apparatus according to claim 20, wherein the RF microcoil comprises Cu and Al.

22. A method for manufacturing an apparatus for manipulation and analysis of a cell, comprising:
forming a planar microcoil on a substrate;
fabricating a CMOS integrated circuit (IC) on the substrate;
attaching the substrate having the planar microcoil and CMOS IC to a Si wafer or PCB having electrical connections;
coating the substrate and the Si wafer or PCB with a photoresist;
patterning the photoresist to define channel sidewalls of a micro-chamber and to provide open areas for external connections;
forming holes on a conductive lid for fluidic tube fittings; and
sealing the conductive lid on the channel sidewalls.

23. The method according to claim 22, wherein the conductive lid is spaced 3-400 μm from a top surface of the substrate.
